(19) United States
(12) Patent Application Publication
(10) Pub. No.: US 2013/0130427 A1
(43) Pub. Date: May 23, 2013

(54) METHOD FOR INCREASING THE TRANSLUCENCY OF A SUBSTRATE

(71) Applicant: Innovent e.V., Jena (DE)

(72) Inventors: Arnd SCHIMANSKI, Erfurt (DE); Andreas HEFT, Gera (DE); Thomas STRUPPERT, Jena (DE); Uwe GITTER, Hermsdorf (DE)

(73) Assignee: Innovent e.V., Jena (DE)

(21) Appl. No.: 13/718,551

(22) Filed: Dec. 18, 2012

Related U.S. Application Data
(63) Continuation of application No. PCT/EP2011/060190, filed on Jun. 20, 2011.

(30) Foreign Application Priority Data
Jun. 21, 2010 (DE) DE102010024521.6

(51) Int. Cl. H01L 31/18

(52) U.S. Cl. CPC H01L 31/18
USPC 438/69

(57) ABSTRACT

A method for increasing a translucency of a substrate is provided, whereby a scattering layer is deposited on the light exit side by means of chemical vapor deposition at atmospheric pressure using a flamer of a plasma, the scattering layer contains either zinc oxide or aluminum and/or aluminum oxide, more particularly aluminum-doped zinc oxide or silicon oxide.

This nonprovisional application is a continuation of International Application No. PCT/EP2011/060190, which was filed on Jun. 20, 2011, and which claims priority to German Patent Application No. DE 10 2010 024 521.6, which was filed in Germany on Jun. 21, 2010, and which are both herein incorporated by reference.

### BACKGROUND OF THE INVENTION

1. Field of the Invention

The invention relates to a method for increasing the translucency of a substrate.

2. Description of the Background Art

Photovoltaic modules, particularly thin-layer modules, comprise a photoactive layer, which is disposed under a protective pane. A transparent conductive oxide layer (TCO—transparent conductive oxide), which serves the photoactive layer as an electrode, is provided on a light exit side of the protective pane, therefore facing the photoactive layer. As much light as possible should be coupled into the photoactive layer for a high efficiency of the photovoltaic module. This can be achieved, for example, by increasing the scattering on the light exit side, so that less light is reflected. The increase in scattering can be achieved, for example, by etching, radiation, or coating. An option is the patterning of the TCO layer. To this end, the TCO layer is applied in a thickness of up to 1 μm and then etched back again by up to 50%. In this way, depending on the crystal structure of the TCO layer, a rough surface arises, which scatters the light emerging from the protective pane and thus reduces the reflection. As a result, the translucency of the protective pane increases, i.e., the amount of the light striking the photoactive layer.

TCO layers for the photovoltaics are generally applied to glass surfaces by sputtering in vacuum. The production of the layers must occur under optimal conditions, because both a maximum translucency and a maximum electrical conductivity are sought. Therefore, this concerns a cost- and time-intensive work step. The etching rates depend greatly on the deposition conditions of the layer and therefore vary considerably. The resulting faulty etchings are a major technical problem.

U.S. Pat. No. 6,436,541 B1 discloses an antistatic coating, having two or more layers, on a substrate. Selected layers of the coating can have antistatic or electromagnetic properties. In an embodiment, the layer farthest from the substrate has a refractive index that is smaller than that of the underlying layer. In another embodiment, the surface of the layer is roughened to obtain a stepped refractive index.

DE 10 2008 025 108 A1 discloses a method for the production of nanoscale electrically conductive multilayer systems on surfaces, whereby the coated surfaces are used in particular for protection from heat or sun or in heating elements. In this case, in a method for coating of substrates with an electrically conductive layer system at least one electrically conductive layer is applied by a flame pyrolysis method.

U.S. Pat. No. 6,924,037 B1 discloses a transparent substrate with an antireflection coating, which includes a sequence of thin layers of a dielectric material, having alternately high and low refractive indexes. This sequence comprises a first layer with a refractive index n between 1.8 and 2.2 and a geometric thickness e₁ between 5 nm and 50 nm, a second layer with a refractive index n₂ between 1.35 and 1.65 and a geometric thickness e₂ between 5 nm and 50 nm, a third layer with a refractive index n₃ between 1.8 and 2.2 and a geometric thickness e₃ between 70 nm and 120 nm, and a fourth layer with a refractive index n₄ between 1.35 and 1.65 and a geometric thickness e₄ of at least 80 nm.

DE 10 2008 033 941 A1 discloses a method for coating a substrate, in which a plasma jet is generated from a working gas, in which at least one precursor material is supplied to the working gas and/or the plasma jet and made to react in the plasma jet, and in which at least one reaction product of at least one of the precursors is deposited on at least one surface of the substrate and/or on at least one layer disposed on the surface, whereby a dye is deposited in at least one of the layers.

U.S. 2009/0229667 A1 discloses a translucent solar cell, which has a transparent substrate and a first translucent electrode that is an anode. A transparent active layer, which is substantially an organic material layer, is formed on top of the anode. A second translucent electrode is formed on the active layer. The second translucent electrode is the cathode. In a variation, the first translucent electrode is the cathode and the second translucent electrode the anode.

JP 2010 067 956 A discloses a reflection-preventing layer for a solar battery. The reflection-preventing layer for a solar battery comprises a layer with a low dielectric constant, which is formed from a material with a first dielectric constant, a layer with a high dielectric constant, which is formed from a material with a second dielectric constant, which is higher than the first dielectric constant, and a gradient layer, which is disposed between the layer with the low dielectric constant and the layer with the high dielectric constant so that its dielectric constant increases from the first dielectric constant to the second dielectric constant.

### SUMMARY OF THE INVENTION

It is therefore an object of the invention to provide an improved method for increasing the translucency of a substrate.

In a method of the invention for increasing the translucency of a substrate, particularly a translucent or transparent substrate, a scattering layer is deposited on a light exit side of the substrate by means of chemical vapor deposition at atmospheric pressure with use of a flame or plasma, the scattering layer can contain either zinc oxide and aluminum and/or aluminum oxide, particularly aluminum-doped zinc oxide (ZnO:Al) or silicon oxide, for example, silicon dioxide. During deposition from flame (Pyrosil technique), at least one precursor is supplied to the flame and made to react in the flame. At least one of the reaction products of the precursor is then deposited as a scattering layer on the light exit side of the substrate. In plasma-supported chemical vapor deposition, at least one precursor is supplied to the plasma or working gas, from which the plasma is generated, and made to react in the plasma. At least one of the reaction products of the precursor is then deposited as a scattering layer on the light exit side of the substrate.

The scattering layers deposited by means of the method of the invention due to the selected method of chemical vapor deposition have the desired rough surface structure and thus increase the proportion of scattered light.

In the case of the scattering layer (ZnO:Al) containing zinc oxide and aluminum and/or aluminum oxide, the scattering layer itself has the properties of a transparent conductive oxide layer (TCO), so that it can be used in direct contact with a photoactive layer of a photovoltaic module, particularly a thin-layer module. Zinc- and aluminum-containing precursors are used to generate the scattering layer.

In the case of the silicon oxide-containing scattering layer, the subsequent TCO layer can be applied in a relatively small thickness to the scattering layer. In this regard the TCO layer reproduces on its surface substantially the rough surface of the scattering layer. Silicon-containing precursors, for example, hexamethyldisiloxane (HMDSO), are used to generate the scattering layer.

In comparison with known methods, in which a large part of the applied TCO layer must be again removed by wet-chemical means (back etching), the cost in the method of the invention is much lower and therefore more cost-effective, because only as much TCO as is absolutely necessary needs to be applied. This reduces the photovoltaic module production costs.

The atmospheric-pressure plasma techniques require substantially lower technical effort, because a treatment of the surface to be coated in vacuum is eliminated. In the atmospheric-pressure plasma method, the particles form in the plasma jet. The size of the agglomerates forming from these particles and therefore the main properties of the coating can be adjusted, inter alia, by the distance of the plasma source from the surface. The homogeneity of the deposited layers is comparable to that achieved by flame treatment but the required energy input is much lower. Alternatively, the method can also be performed at a slightly reduced atmospheric pressure.

Both the costs for vacuum generation and also a portion of the energy costs decline due to the deposition under atmospheric conditions. The method can be realized with simple and accordingly cost-effective systems technology.

Moreover, the patterning of the scattering layer occurs during the deposition with the atmospheric pressure method. This is not possible to the desired extent with the use of vacuum methods.

The scattering layer can be applied to any type of optical substrate, particularly transparent or translucent substrates, but also to opaque substrates in which light is to be scattered. The method of the invention allows the adjustment of barrier properties, the scattering effect, and the refractive index, so that the efficiency of the photovoltaic modules is improved. The barrier effect prevents or makes more difficult the diffusion of ions from the substrate or from the scattering layer. For example, glass or transparent plastics are considerations as a substrate. In the case of transparent plastics, the barrier effect can prevent the diffusion of additives, so that brittleness is averted.

In an embodiment of the invention, another scattering layer can be deposited on the silicon oxide-containing scattering layer by means of a sol-gel process.

During the sol-gel coating, a precursor is dissolved in a solvent and combined with a catalyst, for example, an acid. Said sol is applied to the surface to be coated and dried, so that the crosslinking begins. The resulting network is called a gel. After the drying, a tempering of the layer can occur, for example, at a temperature of at least 150° C. (preferably at least 300° C.), whereby the layer is completed cross-linked. The thus produced layer is mechanically stable.

The scattering layer generated by means of chemical vapor deposition offers a good adhesion base for the sol-gel scattering layer due to its rough surface and its surface composition with a high density of OH groups. The sol-gel scattering layer can bring about further improvement in the scattering because of a correspondingly rough surface structure. For example, in a first step a scattering layer with a thickness of about 200 nm can be deposited from the flame. Next, a sol-gel scattering layer with a thickness of about 100 nm is deposited on this scattering layer.

A transparent conductive oxide layer for use as an electrode in a photovoltaic module, particularly a thin-layer module, can also be deposited on the sol-gel scattering layer.

A deposition of the scattering layer is also possible solely by means of the sol-gel process.

The transparent conductive oxide layer can be deposited by means of any method, but preferably by means of sputtering. For example, first a scattering layer of silicon oxide can be deposited by means of flame or plasma at atmospheric pressure. Next, a zinc oxide- and aluminum-containing TCO layer is deposited by sputtering. Sputtering is especially suitable for depositing on large substrates. Because sputtering is carried out in vacuum, an especially good homogeneity of the deposited layers is achievable.

In an embodiment, nanoparticles, which are deposited in the scattering layer, are added to the precursor used in the deposition of one of the scattering layers. The scattering can be improved in addition in this way. Likewise, the conductivity can be improved by the nanoparticles.

According to an embodiment of the invention, the scattering layer is deposited with a layer thickness of at least 200 nm. This enables a desired roughness of from 40 nm to 60 nm.

The deposition of the scattering layer occurs preferably at a temperature of from 20° C. to 350° C. The substrate is greatly heated in the case of deposition of the scattering layer from flame. Additional heating of the substrate for subsequent coating processes, for example, the deposition of the TCO layer, is thus not necessary. Therefore, a process step can be omitted and the process accelerated.

The substrate processed by means of the method of the invention is preferably used for the production of a photovoltaic cell, particularly a thin-layer photovoltaic cell, whereby a photoactive layer of the photovoltaic cell is disposed in contact either with the zinc oxide- and aluminum-containing scattering layer or with the transparent conductive oxide layer.

### DETAILED DESCRIPTION

Exemplary embodiments of the invention will be described in greater detail below.

A float glass pane of typical thickness was provided as the substrate and purified. Next, a flame treatment of a light exit side of the substrate occurred with the following parameters: Propane (20 L/min to 200 L/min, preferably 20 L/min to 100 L/min) as the fuel gas and air (500 L/min to 1500 L/min, preferably 500 L/min to 1000 L/min) were supplied in a mixture to a band burner with a width of 1.30 m. A liquid precursor mixture, having HMDSO (hexamethyldisiloxane) and a solvent in a volume ratio in the range of 10:90 to 90:10, preferably 20:80 to 50:50, with a flow rate in the range of 1 mL/min to 10 mL/min, was supplied via a nozzle to this fuel gas-air mixture. In this case, all ingredients were combined homogeneously and entered the burner and thereby the flame in the form of gas.

The substrate was passed under the burner with a downwardly directed flame at atmospheric pressure a total of four times at a constant speed in the range of 10 mm/s to 100 mm/s, preferably 10 mm/s to 30 mm/s, at a distance between 5 mm and 40 mm, preferably between 10 mm and 30 mm, whereby at the beginning of the coating process the temperature of the glass substrate corresponded to the ambient temperature of about 25° C.

A scattering layer deposited in this way contains silicon oxide (SiOₓ) and has a thickness of 324 nm and a roughness of 29 nm (Rₐ).

In another exemplary embodiment, a slit burner with the width of 1.30 m was used, to which the fuel gas-air-precursor mixture was supplied in an analogous manner as to the band burner. 3 L/min to 100 L/min, preferably 3 L/min to 30 L/min of propane and 100 L/min to 500 L/min, preferably 200 L/min to 300 L/min of air, and 0.1 mL/min to 1.0 mL/min of the precursor mixture (HMDSO and a solvent in the volume ratio of 10:90 to 90:10, preferably 20:80 to 50:50) were used. The glass substrates were passed under the burner with a downwardly directed flame at 10 mm/s to 100 mm/s, preferably 10 mm/s to 30 mm/s, at a distance between 2 mm and 25 mm, preferably between 2 mm and 10 mm, a total of twenty times. At the beginning of the coating process, the temperature of the glass substrate corresponded to the ambient temperature of about 25° C.

The scattering layer deposited in this way contains silicon oxide (SiOₓ) and has a thickness of 370 nm and a roughness of 40 nm (Rₐ).

A transparent conductive layer in a relatively small thickness can be applied to the silicon oxide-containing scattering layer.

Instead of the silicon oxide-containing scattering layer, a zinc oxide- and aluminum-containing scattering layer can also be deposited, which simultaneously has the properties of a TCO layer.

Alternatively to the flame treatment, the deposition of the scattering layer can occur by means of plasma-supported chemical vapor deposition at atmospheric pressure.

The scattering layer can also be applied to other types of substrates in which light is to be scattered. For example, glass or transparent plastics are considerations as a substrate.

In an embodiment of the invention, another scattering layer can be deposited on the silicon oxide-containing scattering layer by means of a sol-gel process.

A transparent conductive oxide layer for use as an electrode in a photovoltaic module, particularly a thin-layer module, can also be deposited on the sol-gel scattering layer.

A deposition of the scattering layer is also possible solely by means of the sol-gel process.

The transparent conductive oxide layer can be deposited by means of any method, but preferably by means of sputtering.

The precursor used in the deposition of one of the scattering layers can contain nanoparticles, which are incorporated into the scattering layer.

The substrate processed by means of the method of the invention is preferably used for the production of a photovoltaic cell, particularly a thin-layer photovoltaic cell, whereby a photoactive layer of the photovoltaic cell is disposed in contact either with the zinc oxide- and aluminum-containing scattering layer or with the transparent conductive oxide layer.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for increasing a translucency of a substrate, the method comprising:
depositing a scattering layer, the scattering layer having a substance selected from aluminum-doped zinc oxide or silicon oxide, the scattering layer being deposited on a light exit side of the substrate via chemical vapor deposition by flame or plasma; and
depositing the scattering layer with a layer thickness of at least 200 nm at atmospheric pressure.

2. The method according to claim 1, wherein another scattering layer is deposited on the silicon oxide-containing scattering layer by means of a sol-gel process.

3. The method according to claim 1, wherein a transparent conductive oxide layer is deposited on the silicon oxide-containing scattering layer.

4. The method according to claim 2, wherein a transparent conductive oxide layer is deposited on the scattering layer deposited by a sol-gel process.

5. The method according to claim 3, wherein the transparent conductive oxide layer is deposited by sputtering.

6. The method according to claim 4, wherein the transparent conductive oxide layer is deposited by sputtering.

7. The method according to claim 1, wherein nanoparticles, which are deposited in the scattering layer, are added to a precursor used during the deposition of the scattering layer.

8. The method according to claim 2, wherein nanoparticles, which are deposited in the scattering layer, are added to a precursor used in the deposition of the scattering layer.

9. The method according to claim 1, wherein the deposition of the scattering layer by flame occurs at a temperature of 20° C. to 350° C.

10. The method according to claim 1, wherein the deposition of the scattering layer from plasma occurs at a temperature of 20° C. to 350° C.

11. The method according to claim 2, wherein the layer deposited by the sol-gel process is tempered at at least 150° C.

12. A method for producing a photovoltaic cell, the method comprising:
providing a substrate that is processed by the method according to claim 1; and
disposing a photoactive layer of the photovoltaic cell such that it is in contact with an aluminum-doped zinc oxide-containing scattering layer.

13. A method for producing a photovoltaic cell, the method comprising:
providing a substrate that is processed by the method according to claim 3; and
disposing a photoactive layer of the photovoltaic cell such that it is in contact with the transparent conductive oxide layer.

14. A method for producing a photovoltaic cell, the method comprising:
providing a substrate that is processed by the method according to claim 4; and
disposing a photoactive layer of the photovoltaic cell such that it is in contact with the transparent conductive oxide layer.
